(19) United States
(12) Patent Application Publication
(10) Pub. No.: US 2003/0167429 A1
(43) Pub. Date: Sep. 4, 2003

(54) Boundary scan with mode control cells

(76) Inventors: Karlheinz Krause, Planegg (DE); Thomas Kopp, Bad Schonborn (DE)

Correspondence Address: Kevin R. Spivak, Morrison & Foerster LLP, Suite 300, 1650 Tysons Boulevard, McLean, VA, 22102, US

(21) Appl. No.: 10/359,301

(22) Filed: Feb. 6, 2003

(30) Foreign Application Priority Data
Feb. 6, 2002 (DE) 10204885.1

(51) Int. Cl. G01R 31/28

(52) U.S. Cl. 714/724

(57) ABSTRACT

In an electronic chip, it is desirable for the scan cells to be able to be actuated individually during the processing of JTAG instructions. In a chip having a logic circuit which, during normal operation, receives input data via input buffers and/or forwards output data via output buffers and having scan cells which are arranged between the logic circuit and the input and/or output buffers and which, depending on a mode signal, input scan cell data into the logic circuit instead of the input data and/or forward scan cell data to the output buffers instead of the output data, this is achieved by virtue of the chip featuring at least one mode control cell which produces the mode signal and delivers it to the scan cells.

### CLAIM FOR PRIORITY

This application claims priority to International Application No. 10204885.1 which was filed in the German language on Feb. 6, 2002.

### TECHNICAL FIELD OF THE INVENTION

The invention relates to an electronic chip having a logic circuit, and in particular, to a chip which, during normal operation, receives input data via input buffers and/or forwards output data via output buffers.

### BACKGROUND OF THE INVENTION

Electronic chips of this type are frequently in the form of application specific integrated circuits (ASICs) which, following their manufacture, are subjected to extensive qualification procedures. ASICs are a collection of circuits having single functions, such as flipflops, inverters, NANDs, NORs, and of more complex structures such as memory arrangements, adders, counters and phase locked loops. The various circuits are combined in an ASIC in order to implement a particular application. In this context, ASICs are used in a large number of products, e.g. consumer products such as video games, digital cameras, in vehicles and PCs, and in high-end technological products, such as workstations and supercomputers.

To test the functionality of the ASIC, various “Design For Test” (DFT) methods are known The advantage of DFT methods is that the chip's actual design stage involves circuit elements being added which permit subsequent scan-based testing, reduce the number of test points required on the ASIC's board and at the same time get around the problem of access points not being available on the chip.

An example of a DFT method is the “Boundary Scan” (BS) method, which is a chip and board test method standardized on the basis of IEEE 1149. Details regarding boundary scan are described, by way of example, in the book “Boundary Scan Test: Practical Approach” H. Bleeker, Klower Academic Publishers, 1993, ISBN 0-7923-9296-5. The boundary scan method is the basis for all connection tests at board level during the production of complex printed circuit boards (PCBs). For this reason, this standard is also implemented in other integrated circuits and ASICs.

FIG. 1 shows an example of a conventional ASIC 1 having an implemented boundary scan test logic section based on IEEE standard 1149.1. To avoid repetition, only certain features of the known ASIC 1 are being highlighted in this case, and at the same time reference is made to the standard IEEE 1149.1 incorporated in the present application. The ASIC 1 features a core-specific or user-specific logic circuit 2 which, during normal operation, receives input data via input buffers 3, processes them and forwards them to output pins (not shown) via output buffers 4. The logic circuit 2 contains the various circuit elements forming the specific function of the ASIC 1. To perform the boundary scan, the ASIC 1 features a JTAG interface comprising five pins (TDI, TMS, TCK, TRST and TDO).

In line with the standard IEEE 1149.1, a plurality of data registers 5 are defined, two of which, namely the boundary scan register, BS register for short, 6 and the bypass register 7 are necessary registers. The BS register 6 comprises boundary scan cells, BS cells for short, 8 which can be connected together by means of a shift register line 9 to form a shift register. In this context, the BS cells 8 comprise, inter alia, input cells 8a, output cells 8b and control cells (not shown) for controlling the input and output buffers 3, 4. The BS register 6 is used for testing the connections between circuits and possibly also for testing the internal logic circuit 2. In this context, test vectors are inserted serially by the boundary scan cells 8 via the TDI pin and can likewise be ejected serially when required via the TDO pin.

In addition, an instruction register 10 having an instruction decoder 11 and a shift register 12 is prescribed in accordance with the standard. If the instruction register 12 is connected into the TDI/TDO path, instructions can be inserted into the register 12 and are decoded by the instruction decoder 11. These instructions comprise a series of optional instructions and standard instructions, among which only the instructions EXTEST and SAMPLE/PRELOAD are highlighted in the present case. The EXTEST instruction permits execution of a connection test which tests the connection between the output from a logic circuit 2 and the input to another logic circuit. This involves the BS register 6 being connected into the TDI/TDO path. The SAMPLE/PRELOAD instruction is used for sampling the external signal response on the input pins. Although the BS register 6 is connected into the TDI/TDO path by the instruction, the logic circuit 2 remains in the normal operating mode. The instruction permits a snapshot of the flow of data from the input pins to the logic circuit 2 on the input-side boundary scan cells 8a or of the flow of data from the logic circuit 2 to the output pins on the output-side boundary scan cells 8b. The SAMPLE/PRELOAD instruction can also be used to load known data patterns into the output cells 8b for subsequent operations while the logic circuit is in normal operation.

To control the registers 5, the IEEE 1149 architecture makes provision for a plurality of control signals, subsequently denoted by mode signal, clock signal, update signal and shift signal. The signal known as the mode signal in the prior are but referred to as the global mode signal within the scope of this application controls, inter alia, multiplexers contained in the BS cells 8, both in the input direction and in the output direction. If the global mode signal has been set to 1, the multiplexers are switched such that data from the input cells 8a are input into the logic circuit 2 independently of the data in the input buffers 3, and the data in the output cells 8b are forwarded to the output buffers 4 independently of the output data from the logic circuit 2. If the global mode signal is equal to zero, the multiplexers are switched such that the BS cells 8 do not influence the input and output of data into the logic circuit 2.

Table 1 below shows the value of the global mode signal for various “JTAG instructions” provided in the standard IEEE 1149.1. It can thus be seen that, during an EXTEST instruction, for example, the output (IO pin) of the associated output cell, or, to be more precise, of a flipflop contained in the output cell, is driven.

TABLE 1

| | Global mode | |
|---|---|---|
| Instructions | signal | Outputs defined by |
| EXTEST | 1 | BS register |
| SAMPLE/PRELOAD | 0 | Logic circuit |
| BYPASS | 0 | Logic circuit |
| IDCODE | 0 | Logic circuit |
| CLAMP | 1 | BS register |
| INIT | 1 | BS register |

The control signals, including the global mode signal, are defined by a tap controller 13. In this context, the global mode signal can alternatively be delivered to the BS cells 8 by the instruction decoder 4 directly.

The module test, particularly during the production of components, is performed more and more using the BS method described above. Accordingly, the hardware is provided in advance in accordance with the standard IEEE 1149.1. For module testing (connection tests), the instruction EXTEST is used in particular. This instruction involves the inputs and outputs being subject to control by the BS cells 8. In this case, the signals at the inputs and outputs can be generated only using the BS method. If special signals are now required, however, such as a system clock which is generated by the logic circuit 2 and is in turn needed by other circuits, then the EXTEST instruction must be dispensed with completely. If, in the case of conventional components, the situation is thus that module testing involves dependency on particular signals from the core or from the logic circuit which cannot be generated using the BS method, the entire chip in question cannot be used for the connection test, which results in a low level of test coverage.

### SUMMARY OF THE INVENTION

The invention relates to an electronic chip having a logic circuit which, during normal operation, receives input data via input buffers and/or forwards output data via output buffers, having scan cells which are arranged between the logic circuit and the input and/or output buffers and which, depending on a mode signal, input scan cell data into the logic circuit instead of the input data and/or forward scan cell data to the output buffers instead of the output data.

The invention seeks to provide an electronic chip in which the chip's inputs and outputs (IOs) can each be switched individually during normal operation and during test operation of the chip.

The invention, therefore, discloses an electrical chip which has at least one mode control cell which produces the mode signal and delivers it to the scan cells.

This has the advantage that, by introducing the additional cell type for the mode control cell used for controlling the mode signal for the multiplexers associated with an IO pin, it is possible to control whether the data in the output cell 8b or the internal signal in the logic circuit 2 can be present on the IO pin, specifically including during the EXTEST instruction, for example.

In one advantageous embodiment of the present invention, the mode control cell can be connected to the scan cells to form a shift register. In this regard, control data can be inserted into the mode control cells together with other boundary scan data without any particularl additional complexity.

In another embodiment of the present invention, the data which the shift register inserts into the mode control cell form the mode signal, which means that mode signal influencing is achieved irrespective of any JTAG instructions available.

In another embodiment of the present invention, one mode control cell is connected to at least one of the scan cells and delivers the mode signal thereto. In this context, central actuation of all BS cells is possible, and the number of mode control cells needing to be implemented is minimized.

In still another embodiment of the present invention, the mode control cell receives a global mode signal which is modified on the basis of the data in the mode control cell and is output as the mode signal. This provides compatibility with the prior standard IEEE 1149.1, which makes provision for the global mode signal.

In line with one advantageous aspect, at least one of the scan cells is a control cell which controls the state of an output buffer in order to be able to control the chip's output buffers individually.

In line with a further aspect, at least one of the scan cells is an output cell which is connected to an output buffer and forwards data thereto in order to be able to carry out a connection test.

In line with another aspect, at least one of the scan cells is an input cell which is connected to the logic circuit and forwards data thereto in order to tap off data entering the chip via the input buffers, for the purpose of carrying out an input-side connection test, and in order to be able to input data into the logic circuit.

In line with still another aspect, the scan cells form triplets which comprise a control cell, an output cell and an input cell, with a respective mode control cell being connected to the scan cells of a triplet and delivering the mode signal thereto. This achieves a particularly high level of flexibility, which is desirable in programmable logic devices (PLDs), for example.

In line with another embodiment, the mode control cell has a first flipflop forming part of the shift register in order to allow the control data to be inserted within the context of the boundary scan method.

In line with a further embodiment, the mode control cell has a second flipflop which receives the output from the first flipflop as its input in order to be able to store the control data in the mode control cell.

In another embodiment, the mode control cell features an inverter which receives the global mode signal as its input and outputs the global mode signal in inverted form, in order to provide for particularly simple and inexpensive implementation of the mode control cells within the context of the boundary scan method.

In still another embodiment, the mode control cell has a mode signal multiplexer which receives the global mode signal and the inverted global mode signal, with the control input of the multiplexer being connected to the output of the second flipflop, and with the mode signal multiplexer outputting the global mode signal or the inverted global mode signal to the scan cells as a mode signal on the basis of the output from the second flipflop. This provides a particularly simple circuit for modifying the present global mode signal using control data in the mode cell.

In another embodiment, the mode control cell has an XOR gate which inverts the global mode signal and inputs it into the mode signal multiplexer. With this solution, which can be regarded as an alternative to the inverter, an inverted global mode signal can be produced in a particularly simple manner.

In yet another embodiment, the mode control cell is in the form of a mode control block, where the mode control block has a first modified mode control cell and a second modified mode control cell which respectively include first and second flipflops and are connected in series in the shift register, and where, in addition, the first modified mode control cell features an extended mode signal multiplexer which is actuated by the second flipflop in the first modified mode control cell and by the second flipflop in the second modified mode control cell. With this embodiment, it is possible to ensure that particular I/Os can be decoupled from JTAG instructions immediately, without interruption.

### BRIEF DESCRIPTION OF THE DRAWINGS

Exemplary embodiments of the invention and further features and advantages are described in more detail below with reference to the drawings, in which:

FIG. 1 shows a conventional electronic chip with boundary scan test logic.

FIG. 2 shows boundary scan cells and of a mode control cell in an ASIC in accordance with a first exemplary embodiment of the present invention.

FIG. 3 shows mode control cells in an ASIC in accordance with a second exemplary embodiment of the present invention.

### DETAILED DESCRIPTION OF THE INVENTION

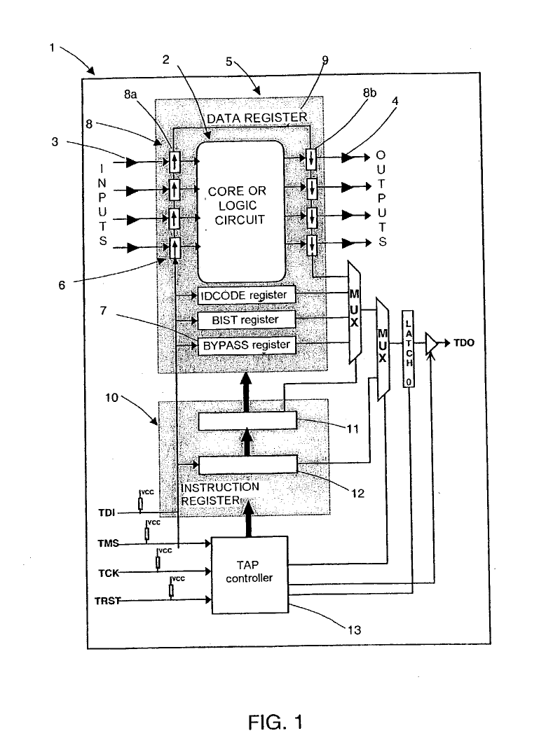

FIG. 1 shows a conventional electronic chip 1, in this case an ASIC, with boundary scan implementation in line with the standard IEEE 1149.1. The present invention is based on such a chip 1. To avoid repetition, reference is made below to the chip described in the introduction to the description, referring to FIG. 1.

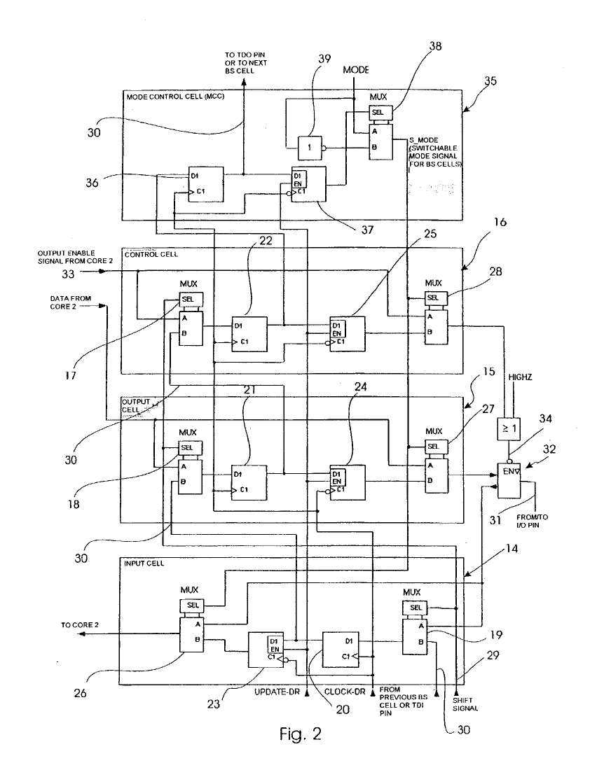

With reference to FIG. 2, the exemplary arrangement of the BS cells 8, also referred to below as scan cells, in an inventive chip will now be illustrated in detail. The BS cells 8 feature at least one input cell 14 and/or at least one output cell 15 and/or at least one control cell 16. Each of the BS cells 14, 15, 16 has a respective input multiplexer 17, 18, 19, a respective register flipflop (register FF) 20, 21, 22, additionally a respective update flipflop (update FF) 23, 24, 25, and finally a respective output multiplexer 26, 27, 28.

The register FFs 20, 21, 22 are clocked by a broadcast signal (i.e. a signal which is output centrally to a plurality of elements) CLOCK_DR and, according to the switching of the input multiplexer 17, 18, 19, receive data either from the preceding BS cell 14, 15, 16 or from the logic circuit 2 (in the case of the input cell 14 from the IO pin) upon the rising edge. The update FFs 23, 24, 25 receive the data from the register FFs 20, 21, 22 and likewise receive the CLOCK_DR clock signal. In a preferred exemplary embodiment, the CLOCK_DR signal at the input of the update FFs 23, 24, 25 is inverted, which is indicated by the circle in FIG. 2. In addition, the update FFs receive a further broadcast signal UPDATE-DR, however, which signals that the data will be output from the update FFs 23, 24, 25 upon the next falling edge of the CLOCK_DR signal. The data stored in the update FF are also referred to below as scan cell data.

It will be noted at this point that the standard IEEE 1149.1 describes only the boundary scan functionality, i.e. no specifications are defined for integrating said standard into the circuit. For this reason, the structures used here for the BS cells 8 will be regarded merely as examples.

The scan cells 14, 15, 16—to be more precise the input multiplexers 17, 18, 19—receive a shift signal 29 from the TAP controller 13 and can be connected together by means of a shift register line 30 to form a shift register. Via the mode control lines 31, the output multiplexers 26, 27, 28 receive a mode signal (S_MODE) which determines whether the scan cells are in normal mode or in test mode. The individual BS cells 14, 15, 16 will now be described individually in normal mode and in test mode.

In normal mode, i.e. S_MODE=0, the input cell 14 receives data from a buffer 32 and forwards them to the logic circuit 2 via the output multiplexer 26. In test mode, i.e. S_MODE=1, the output multiplexer 26 for the input cell 14 is switched such that, upon the next clock pulse from UPDATE-DR and upon the next falling edge of CLOCK-DR, the data from the update FF 23 will be forwarded to the logic circuit 2. The data from the update FF 23 have previously been taken from the register FF 20, which in turn received them either via buffer 32 or via shift register line 30, depending on the level of the shift signal 29.

In normal mode, the output cell 15 receives data from the logic circuit 2 and forwards them directly to buffer 32 on the basis of the corresponding switching of the output multiplexer 27. In test mode, the output multiplexer 27 is switched such that data from the update FF 24 are applied to buffer 32 and hence to the output pin. Depending on the level of the shift signal 29, the data have previously been inserted via the register FFS 20 and can now be used for the connection test.

In normal mode, the control cell 16 receives an output enable signal 33 from the logic circuit 2 and forwards it via the output multiplexer 28 to a control input 34 for the buffer 32. In the preferred exemplary embodiment, the buffer 32 comprises at least one tristate buffer 32 which can be turned off, turned on or switched to a high-impedance state (high Z) by means of the output enable signal 33, specifically in order to communicate with the I/O pin (not shown) via the I/O line 31. In test mode, data contained in the update FF 25 are forwarded to the control input 34 of the buffer 32 via the output multiplexer 28 as control data. The data in the update FF 25 have previously been taken from the register FF 22, which in turn received them via shift register lines 30 or from the logic circuit 2, depending on the level of the shift signal 29.

To generate the mode control signal S_MODE, the inventive chip features at least one mode control cell 35. The mode control cell 35 has a first flipflop (FF) 36 which is connected in series with the other BS cells 14, 15, 16 by means of a shift register line 30. Like the register FFs 20, 21, 22, the first FF 36 is clocked by means of the signal CLOCK-DR. In addition, the mode control cell 35 has a second flipflop (FF) 37 which, like the update FFs 23, 24, 25, is clocked by means of the signals CLOCK-DR and UPDATE-DR and receives the output from the first FF 36 as its input. In addition, the mode control cell 35 features a mode signal multiplexer 38 which is controlled via the output of the second FF 37.

In the preferred exemplary embodiment, the mode control cell 35 receives the global mode signal (MODE) directly via connecting lines from the instruction decoder 11. By contrast, in other exemplary embodiments, the mode control cell is connected to the TAP controller 13 and receives the global mode signal therefrom. The global mode signal is firstly input directly into the mode signal multiplexer 38 and is secondly likewise input into the mode signal multiplexer 38 as a second input variable via an inverter 39 associated with the mode control cell 35. Depending on the JTAG instructions in the BS method, the global mode signal (MODE) has the value 1 or 0 (see Table 1). This signal is modified by the provision of the mode control cell 35 on the basis of the data included in the second FF 37 and is forwarded to the BS cells 14, 15, 16 as a mode signal (S_MODE). In a preferred exemplary embodiment, when there is a logic “1” in the second FF 37, the inverted MODE, generated by the inverter 39, is forwarded as a mode signal S_MODE, whereas, when there is a “0” in the second FF 37, the global mode signal is forwarded unchanged as S_MODE. The second FF 37 receives its data from the first FF 36. Since the first FF 36 is part of the scan line or of the shift register, control data can thus be inserted as a test vector via the TDI in order to control the S_MODE. This results in the following advantages:

During the JTAG instructions (such as EXTEST), in which the IOs are normally controlled exclusively via the BS cells 14, 15, 16, the at least one mode control cell 35 can nevertheless be used to take on mode actuation, so that the IOs can be used individually.

This allows special signals, such as the system clock, to be made available during the connection test as well, since the BS cell responsible for the system clock's I/O can be put into the normal mode individually by appropriately inserting data into the second FF 37 in the mode control cell 35.

During normal operation (i.e. global mode signal MODE=0) quite specific signals (inputs or outputs) can be put into any desired state, so that fault insertion is possible on selectable chip interfaces using the EXTEST instruction.

During normal operation (MODE=0), quite specific signals (inputs or outputs) can be put into any desired state, so that mode or control functions of a chip can be handled using the JTAG interface. An example of this would be the start of the BOST (board self test) or the setting of a particular mode of operation.

While the description above has described one mode control cell 35 and its control by a respective output, input and control cell 15, 14, 16, it should be obvious to a person skilled in the art that there are a large number of arrangement options for the mode control cell 35, or a plurality of mode control cells can be provided. In the preferred exemplary embodiment, one mode control cell 35 controls any number of BS cells 8 arranged in the chip. In this context, the mode control cell can be arranged at any position in the shift register.

In another exemplary embodiment, which can be used particularly in relation to programmable logic devices (PLDs), a large number of BS cells 8 contained in the chip are advantageously split into triplets which respectively comprise a control cell 16, an output cell 15 and an input cell 14 and are associated with an IO pin. Each of these triplets would then be assigned an individual mode control cell 35, with the mode control cell 35 generating the mode signal S_MODE for the triplet. The plurality of mode control cells receive the global mode signal MODE and generate individual mode signals S_MODE which can differ from one another.

In another exemplary embodiment, each BS cell 8 is assigned an individual mode control cell 35 in order to provide a very high degree of flexibility for the individual control of the BS cells 8. In general, it holds true for the control of the BS cells 8 that any number of BS cells 8 can be combined, so that the number of mode control cells 35 is kept low.

The text below now describes individual exemplary applications of the inventive controllable masking of dedicated IOs.

Fault Insertion:

The aim in the case of fault insertion is to keep inputs and/or outputs at a particular potential during normal operation (MODE=0). To this end, the SAMPLE/PRELOAD instruction is first used to write to the mode control cell 35 (MCC) such that the inputs and/or outputs in question are connected to BS cells 8 (S-MODE=1 for the corresponding BS cells 8). This is done from the time of the UPDATE-DR signal onward. The state of the signal in question (HIGH=1, LOW=0, high impedance state) is dependent on the associated BS cell 8.

The rest of the BS cells 8 remain in normal mode, i.e. S_MODE=0. Return from the fault insertion state is effected by further writing to the MCCs 35. The EXTEST instruction is not required for this purpose. A command sequence for entering and exiting the fault insertion mode is shown in Table 2:

TABLE 2

| Instruction | MODE | MCC | S_MODE | Source for IO pin |
|---|---|---|---|---|
| Normal operation | 0 | 0 | 0 | Logic circuit |
| SAMPLE UPDATE IR | 0 | 0 | 0 | Logic circuit |
| SAMPLE UPDATE DR | 0 | 1 | 1 | BS cell |
| SAMPLE UPDATE DR | 0 | 0 | 0 | Logic circuit |
| Normal operation | 0 | 0 | 0 | Logic circuit |

Control Functions:

The aim in this case is to keep inputs and/or outputs at a particular potential during normal operation.

To this end, like in the exemplary application of fault insertion, the SAMPLE/PRELOAD instruction is first used to write to the mode control cell (MCC) such that the inputs and/or outputs in question are connected to BS cells 8 (S-MODE=1 for the corresponding BS cells 8). This is done from the time of the UPDATE-DR signal onward. The state of the signal in question (HIGH=1, LOW=0, high impedance state) is dependent on the associated BS cell 8.

The rest of the BS cells 8 remain in normal mode, i.e. S_MODE=0. Return from the fault insertion state is effected by further writing to the MCCs 35. The EXTEST instruction is not required for this purpose. A command sequence for entering and exiting the control mode is shown in Table 3:

TABLE 3

| Instruction | MODE | MCC | S_MODE | Source for IO pin |
|---|---|---|---|---|
| Normal operation | 0 | 0 | 0 | Logic circuit |
| SAMPLE UPDATE IR | 0 | 0 | 0 | Logic circuit |
| SAMPLE UPDATE DR | 0 | 1 | 1 | BS cell |
| SAMPLE UPDATE DR | 0 | 0 | 0 | Logic circuit |
| Normal operation | 0 | 0 | 0 | Logic circuit |

System Clock Application:

The aim here is to connect inputs and/or outputs to the logic circuit during test operation (i.e. MODE=1).

A) Solution With Interruption

In this context, the exemplary embodiment for FIG. 2 is used. First, the EXTEST instruction is used to put the global mode signal with UPDATE-IR to MODE=1 (test operation). Next, the MCCs 35 are loaded such that the inputs and outputs in question (i.e. the outputs at which the logic circuit 2 outputs the system clock) with UPDATE-DR are connected to the logic circuit 2 (S_MODE=0 for the corresponding BS cells 8). The rest of the BS cells 8 remain in test mode (S_MODE=1). Return from this state is effected by further writing to the MCCs 35. This has the following drawback, however: the timing of the signals in question, such as the system clocking, is interrupted by the test mode for the corresponding BS cells from the UPDATE-IR to the UPDATE-DR. A command sequence for the solution with interruption is shown in Table 4:

TABLE 4

| Instruction | MODE | MCC | S_MODE | Source for IO pin |
|---|---|---|---|---|
| Normal operation | 0 | 0 | 0 | Logic circuit |
| EXTEST UPDATE-IR | 1 | 0 | 1 | BS cell |
| EXTEST UPDATE DR | 1 | 1 | 0 | Logic circuit |
| EXTEST UPDATE DR | 1 | 0 | 1 | BS cell |
| Normal operation | 0 | 0 | 0 | Logic circuit |

B) Solution Without Interruption

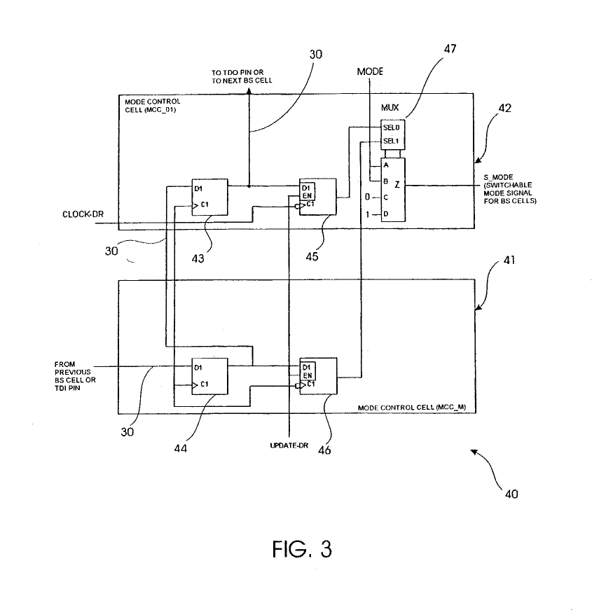

With this application, an exemplary embodiment of the present invention in line with FIG. 3 is used. FIG. 3 shows a mode control block 40 used instead of a mode control cell 35 from FIG. 2. The at least one mode control block 40 comprises a first modified mode control cell 42 (MCC_{—}01) and a second modified mode control cell 41 (MCC_M). The two modified mode control cells 41, 42 each have, like the mode control cell 35 from FIG. 2, a first flipflop (FF) 43, 44, clocked by means of the CLOCK-DR signal, and a second flipflop (FF) 45, 46, clocked by the CLOCK-DR and UPDATE-DR signals.

The two mode control cells 41, 42 with their first FFs 43, 44 in series via a shift register line 30 are arranged in series with one another in the shift register in the BS cells. To be more precise, the input side of the first FF 44 in the MCC_M is connected to a preceding BS cell 8 in the shift register (or to the TDI pin) and its output is connected to the first FF 43 in the MCC_{—}01, and the output side of the first FF 43 in the MCC_{—}01 is in turn connected to the next BS cell 8 (or to the TDO pin) in the shift register.

The first modified mode control cell MCC_{—}01 has an extended mode signal multiplexer 47 having four inputs A, B, C, D, and two control inputs SEL0, SEL1. The MCC-01 42 receives the global mode signal MODE either from the TAP controller 13 or from the instruction decoder 11 and inputs it into both inputs A and B of the extended mode signal multiplexer 47. The input C receives a logic “ZERO” and the input D receives a logic “ONE”. The second FF 45 is connected to the output of the first FF 43 and receives the data therefrom. The output of the second FF 45 is connected to the first control input SEL0 of the extended mode signal multiplexer 47. The second FF 46 in the second modified mode control cell 41 receives the data from the first FF 44 in the second modified mode control cell 41 and forwards them as control data to the second control input SEL1 of the extended mode signal multiplexer 47. Table 5 shows the switching table (or the mode signal S_MODE from the extended mode signal multiplexer 47, which mode signal is output from the extended mode signal multiplexer) as a function of the control or select input signals:

TABLE 5

| SEL1 | SEL0 | Z |
|---|---|---|
| MCC_M | MCC_01 | S_MODE |
| 0 | 0 | MODE |
| 0 | 1 | MODE |
| 1 | 0 | 0 |
| 1 | 1 | 1 |

As in the first exemplary embodiment, the mode signal S_MODE which is output at the output Z is forwarded to at least one BS cell 8 and controls it.

The text below will now describe how the application for maintaining the system clocking during the connection test without interruption can be achieved by using the at least one mode control block 40 from FIG. 3.

The SAMPLE/PRELOAD instruction is first used to set the control cells in the mode control block 40 associated with the inputs and outputs in question to MCC_M=1 and MCC_{—}01=0 (i.e. the corresponding data are inserted into the second flipflops 45, 46 via the first flipflops 43, 44). As Table 5 shows, this results in the mode signal S_MODE=0, i.e. the BS cells 8 to which this signal is supplied are in normal mode. The EXTEST UPDATE-IR instruction is now no longer used to influence the output S_MODE. With the EXTEST UPDATE-DR, it should be noted that the states are maintained for MCC_M and MCC_{—}01. The signals not affected thereby can be incorporated into the boundary test as desired using the EXTEST instructions. In this case, the mode signal S_MODE remains uninterrupted at S_MODE=0 for the inputs and outputs in question. Return from this state is effected by further writing to the first and second modified mode control cells 41, 42 in the SAMPLE/PRELOAD instructions, i.e. setting of MCC_M=0 and MCC_{—}01=0.

An instruction sequence for the solution without interruption described above is shown in Table 6:

TABLE 6

| | | | | | Source for the |
|---|---|---|---|---|---|
| | | | | | system clock's |
| Instruction | MODE | MCC_M | MCC_01 | S_MODE | IO pin |
| Normal operation | 0 | 0 | 0 | 0 | Logic circuit |
| SAMPLE UPDATE IR | 0 | 0 | 0 | 0 | Logic circuit |
| SAMPLE UPDATE DR | 0 | 1 | 0 | 0 | Logic circuit |
| EXTEST UPDATE IR | 1 | 1 | 0 | 0 | Logic circuit |
| EXTEST UPDATE DR | 1 | 1 | 0 | 0 | Logic circuit |
| SAMPLE UPDATE IR | 0 | 1 | 0 | 0 | Logic circuit |
| SAMPLE UPDATE DR | 0 | 0 | 0 | 0 | Logic circuit |
| Normal operation | 0 | 0 | 0 | 0 | Logic circuit |

With this configuration, application combinations (fault insertion, control functions) can likewise be produced. It should also be noted that the comments made regarding an arrangement of one or more mode control cells 35 in the first exemplary embodiment relative to a plurality of BS cells 8 apply similarly for an arrangement of one or more mode control blocks 40 with respect to a plurality of BS cells 8.

The exemplary embodiments described above can be implemented, in principle, in all integrated circuits including boundary scan, with implementation being of particular interest for programmable logic devices (PLDs) and for field programmable gate arrays (FPGAs).

In summary, the inventive provision of mode control cells permits controllable masking of dedicated IOs during JTAG instructions in which the state of IOs is controlled exclusively by means of the boundary scans, such as EXTEST, but also, conversely, permits control of particular I/Os during normal operation. It will be emphasized within this context, however, that there are a large number of arrangement and refinement options for the mode control cells. Thus, in the exemplary embodiment in FIG. 2, for example, the mode signal multiplexer 38 and the inverter 39 could be replaced by an XOR gate receiving the global mode signal MODE and the signal from the second FF 37 as its inputs. Such variations of the refinement fall within the scope of protection of the appended claims, however.

What is claimed is:

1. An electronic chip, comprising:
a logic circuit which, during normal operation, receives input data via input buffers and/or forwards output data via output buffers;
scan cells which are arranged between the logic circuit and the input and/or output buffers and which, depending on a mode signal, input scan cell data into the logic circuit instead of the input data and/or forward scan cell data to the output buffers instead of the output data, wherein
the chip has at least one mode control cell which produces the mode signal and delivers the mode signal to the scan cells.

2. The electronic chip as claimed in claim 1, wherein the at least one mode control cell is configured to be connected to the scan cells to form a shift register.

3. The electronic chip as claimed in claim 2, wherein the data which the shift register inserts into the at least one mode control cell form the mode signal.

4. The electronic chip as claimed in claim 1, wherein the at least one mode control cell is connected to at least one of the scan cells and delivers the mode signal to the at least one scan cell.

5. The electronic chip as claimed claim 1, wherein the at least one mode control cell receives a global mode signal which is modified based on the data in the at least one mode control cell and is output as the mode signal.

6. The electronic chip as claimed in claim 1, wherein at least one scan cell is a control cell which controls the state of an output buffer.

7. The electronic chip as claimed in claim 1, wherein at least one scan cell is an output cell which is connected to an output buffer and forwards data thereto.

8. The electronic chip as claimed in claim 1, wherein at least one scan cell is an input cell which is connected to the logic circuit and forwards data thereto.

9. The electronic chip as claimed in claim 1, wherein the scan cells form triplets which comprise a control cell, an output cell and an input cell, with a respective mode control cell being connected to the scan cells of a triplet and delivering the mode signal thereto.

10. The electronic chip as claimed in claim 2, wherein the at least one mode control cell has a first flipflop forming part of the shift register.

11. The electronic chip as claimed in claim 10, wherein the mode control cell has a second flipflop which receives the output from the first flipflop as an input.

12. The electronic chip as claimed in claim 2, wherein the at least one mode control cell has an inverter which receives a global mode signal as an input and outputs the global mode signal in inverted form.

13. The electronic chip as claimed in claim 12, wherein the at least one mode control cell has a mode signal multiplexer which receives the global mode signal and the inverted global mode signal, with the control input of the mode signal multiplexer being connected to the output of the second flipflop, and with the mode signal multiplexer outputting the global mode signal or the inverted global mode signal to the scan cells as a mode signal on the basis of the output from the second flipflop.

14. The electronic chip as claimed in claim 1, the scan cells are boundary scan cells in accordance with the boundary scan standard IEEE 1149.1.

15. The electronic chip as claimed in claim 12, wherein the at least one mode control cell has an XOR gate which inverts the global mode signal and inputs it into the mode signal multiplexer.

16. The electronic chip as claimed in claim 2, wherein the at least one mode control cell is configured as a mode control block, where the mode control block has a first modified mode control cell and a second modified mode control cell which, respectively, include first and second flipflops and are connected in series in the shift register.

17. The electronic chip as claimed in claim 16, wherein the first modified mode control cell has an extended mode signal multiplexer which is actuated by the second flipflop in the first modified mode control cell and by the second flipflop in the second modified mode control cell.
